(19) United States
(12) Patent Application Publication
(10) Pub. No.: US 2005/0158637 A1
(43) Pub. Date: Jul. 21, 2005

(54) Template, method of forming the template and method of forming a pattern on a semiconductor device using the template

(75) Inventors: Jin-Ah Kim, Seoul (KR); Dong-Seok Nam, Seoul (KR); Jung-Hwan Hah, Suwon-si (KR)

Correspondence Address: F. CHAU & ASSOCIATES, LLC, 130 WOODBURY ROAD, WOODBURY, NY, 11797, US

(73) Assignee: Samsung Electronics Co., Ltd.

(21) Appl. No.: 11/037,805

(22) Filed: Jan. 18, 2005

(30) Foreign Application Priority Data
Jan. 15, 2004 (KR) 2004-2835

(51) Int. Cl. G03F 9/00; G03C 5/00

(52) U.S. Cl. 430/5; 430/323; 430/322; 430/324

(57) ABSTRACT

A template, a method of forming the template and a method of forming a photoresist pattern using a lithographic template is disclosed. In the method, a photoresist film is formed on a substrate. A template for selectively transmitting light is pressed on the photoresist film. The template includes a transparent plate through which light passes, a blocking pattern formed thereon for selectively blocking the light passing through the transparent plate, and a plurality of concave and convex portions for imprinting the photoresist film. The concave and convex portions are formed in accordance with the blocking pattern. The photoresist film is partially exposed to light selectively passing through the template, and the photoresist film that has been exposed to the light is also partially developed to form the photoresist pattern.

### CROSS-REFERENCE TO RELATED APPLICATION

This application claims priority to Korean Patent Application No. 2004-2835 filed on Jan. 15, 2004, the contents of which are herein incorporated by reference in its entirety.

### BACKGROUND OF THE INVENTION

1. Field of the Invention

The present invention relates to a method of manufacturing a semiconductor device. More particularly, the present invention relates to a template, a method of forming the template and a method of forming a pattern on a semiconductor device using the template.

2. Description of the Related Art

As semiconductor devices become highly integrated, a pitch pattern is reduced, thus requiring a width of the pattern to be scaled down. Conventionally, a photolithography process has been used to form a fine pitch pattern by employing a wavelength of light to determine a line width of the pattern.

In a conventional photolithography process the line width of a pattern is typically less than 70 nm. The line width of the pattern widely varies in accordance with the reflection or diffraction of light. For a smaller pattern, even a slight variation in the line width alters the characteristics of the semiconductor device.

As the feature size of recent semiconductor devices decreases into the sub-micron range, there is a need for next generation lithographic (NGL) processes that pattern at such high densities. Several NGL processes for accomplishing this, which are based on imprinting and stamping, have been proposed. In particular, an imprint lithography technique has been shown to be capable of patterning line widths less than about 70 nm.

According to the imprint lithography process, an image is formed on a lithographic template, and then the template makes contact with a monomer layer having a hardening characteristic when exposed to light. Light is then irradiated onto the template, and a molecular structure of the monomer layer is partially varied in accordance with the image, thereby forming a predetermined pattern along the image. Korean Publication Patent No. 2003-040378 discloses an exemplary method of forming a pattern using the imprint lithography technique.

The lithographic template includes a transparent plate, a thin layer coated on the transparent plate and a photoresist film coated on the thin layer. An example of the transparent plate includes a quartz plate, and an example of the thin layer includes a chrome (Cr) layer. Then, the photoresist film is partially removed using either an electron beam or an optical exposure system, thereby forming a photoresist pattern. The quartz plate and the Cr layer are partially etched away using the photoresist pattern as an etching mask, thus the image is formed on the quartz plate. Then, the Cr layer is completely removed from the quartz plate, thereby forming the template including the image. The Cr layer is an adhesion type layer for adhering the photoresist film onto the quartz plate. Meanwhile, a transfer layer comprising an organic antireflective coating (organic ARC) and an imprint layer comprising a monomer having a hardening characteristic when exposed to light are coated on a semiconductor substrate.

Subsequently, the template is brought into contact with the imprint layer using minimal pressure, and light is irradiated onto the substrate through the template. The imprint layer is formed into a preliminary mask pattern in accordance with the image on the template after a predetermined developing process. Then, the transfer layer is partially etched away using the preliminary pattern as an etching mask, thereby forming a mask pattern for partially etching the substrate.

Because the imprint layer is barely adhered to an object layer that is to be patterned, the transfer layer is interposed between the object layer and the imprint layer for improving an adhesion characteristic of the imprint layer. The conventional imprint lithography process, however, forms the mask pattern by performing an etching process twice, once on the imprint layer and once on the transfer layer, thus reducing a thickness of the mask pattern and decreasing an aspect ratio of the mask pattern.

A need therefore exists for a template for forming a photoresist pattern using an imprint lithographic process, a method of forming a lithographic template and a method of forming a photoresist pattern using the lithographic template.

### SUMMARY OF THE INVENTION

According to an aspect of the present invention, there is provided a template for forming a photoresist pattern. The template includes a transparent plate through which light passes, a blocking pattern formed on the transparent plate for selectively blocking the light passing through the transparent plate, and a plurality of concave and convex portions for imprinting the photoresist pattern. The concave and convex portions are formed in accordance with the blocking pattern.

According to another aspect of the present invention, there is provided a method of forming a template by which a photoresist pattern is formed. A transparent plate through which light passes is provided, and a blocking layer is formed on the transparent plate for selectively blocking the light. The blocking layer and the transparent plate are partially removed, so that a blocking layer pattern and a plurality of concave and convex portions are formed for imprinting the photoresist layer.

According to still another aspect of the present invention, there is provided a method of forming a photoresist pattern on a substrate. A photoresist film is formed on the substrate, and a template is pressed on the photoresist film. The template includes a transparent plate through which light passes, wherein a blocking pattern is formed on the transparent plate for selectively blocking the light passing through the transparent plate, and a plurality of concave and convex portions for imprinting the photoresist film. The concave and convex portions are formed in accordance with the blocking pattern. The photoresist film is partially exposed to light selectively passing through the template, and the photoresist film is then developed after being exposed to the light.

### BRIEF DESCRIPTION OF THE DRAWINGS

The above and other features of the present invention will become readily apparent by reference to the following detailed description when considered in conjunction with the accompanying drawings, in which:

FIG. 1A is a plan view illustrating a template for forming a photoresist pattern according to a first exemplary embodiment of the present invention;

FIG. 1B is a cross sectional view illustrating the template shown in FIG. 1A;

FIGS. 2A and 3A are plan views illustrating processing steps of a method of forming the template shown in FIGS. 1A and 1B;

FIGS. 2B and 3B are cross sectional views illustrating processing steps of a method of forming the template shown in FIGS. 1A and 1B;

FIGS. 4A to 4E are cross sectional views illustrating processing steps of a method of forming a photoresist pattern on a semiconductor substrate using the template shown in FIGS. 1A and 1B;

FIG. 5 is a cross sectional view illustrating a template for forming a photoresist pattern according to a second exemplary embodiment of the present invention;

FIGS. 6A and 6B are cross sectional views illustrating processing steps of a method of forming the template shown in FIG. 5;

FIGS. 7A to 7D are cross sectional views illustrating processing steps of a method of forming a photoresist pattern on a semiconductor substrate using the template shown in FIG. 5; and

FIG. 8 is a cross sectional view illustrating a template for forming a photoresist pattern according to a third exemplary embodiment of the present invention.

### DESCRIPTION OF THE EXEMPLARY EMBODIMENTS

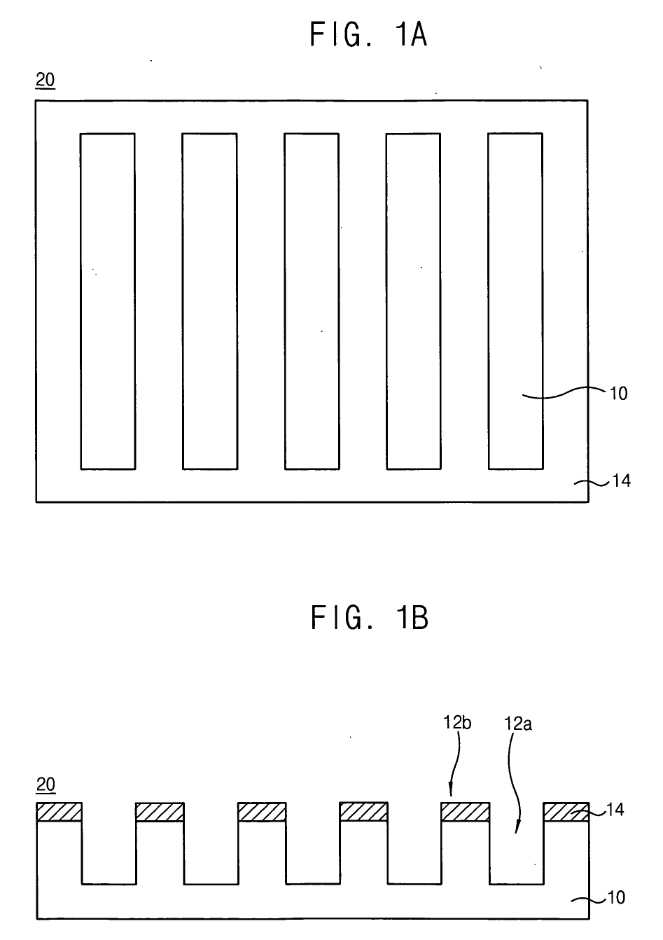

FIG. 1A is a plan view illustrating a template 20 for forming a photoresist pattern according to a first exemplary embodiment of the present invention, and FIG. 1B is a cross sectional view illustrating the template 20 shown in FIG. 1A.

Referring to FIGS. 1A and 1B, the template 20 includes a transparent plate 10 comprising a transparent material such as quartz. A plurality of concave and convex portions 12a and 12b for imprinting patterns is formed on a top surface of the transparent plate 10. The top surface of the transparent plate 10 comes into contact with a semiconductor substrate when an imprinting process is performed. A line of the photoresist pattern is formed on the substrate along the concave portions 12a, and a space between the lines of the photoresist pattern is formed on the substrate along the convex portions 12b during the following imprinting process. A top surface of the convex portions 12b may be planarized.

A blocking layer comprising a metal such as chrome (Cr) is formed on the top surface of the convex portions 12b, and a blocking pattern 14 is formed along the convex portions 12b. Accordingly, the light irradiated onto the template 20 partially passes through the concave portions 12a, and is partially blocked by the convex portions 12b.

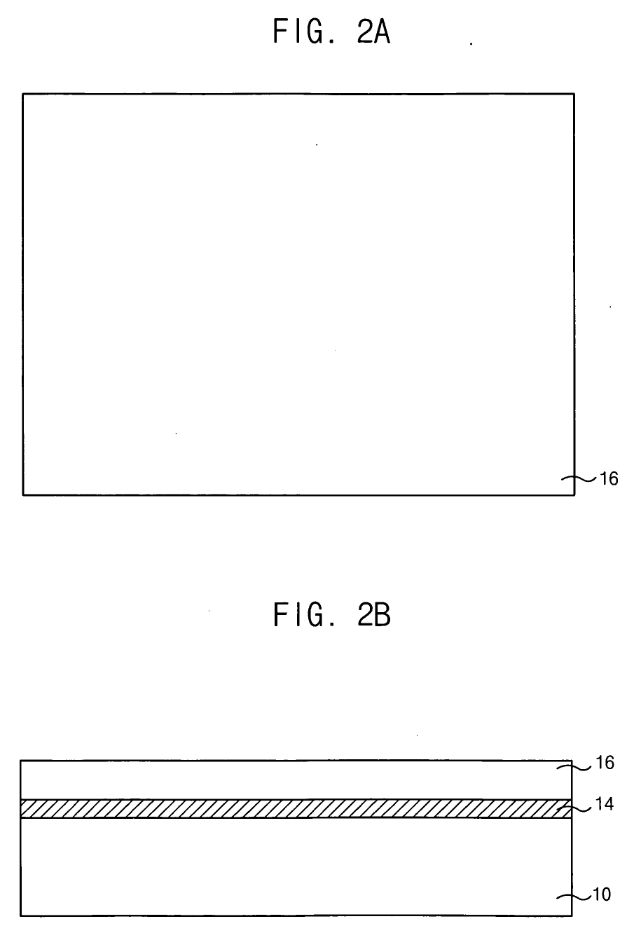

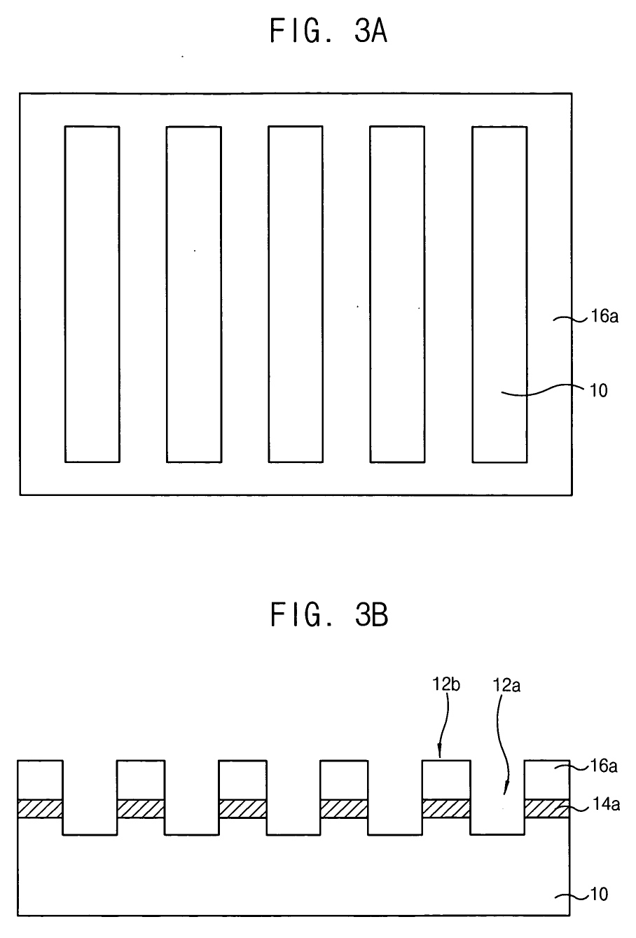

FIGS. 2A and 3A are plan views illustrating processing steps of a method of forming the template 20 shown in FIGS. 1A and 1B. FIGS. 2B and 3B are cross sectional views illustrating processing steps of a method of forming the template 20 shown in FIGS. 1A and 1B.

Referring to FIGS. 2A and 2B, a transparent plate 10 comprising a transparent material, for example quartz, is provided, and light passes through the transparent plate 10. A blocking layer 14 is formed on the transparent plate 10 for selectively blocking the light. For example, the blocking layer 14 may comprise a metal such as Cr. Then, a sacrificial photoresist film 16 is formed on the blocking layer 14. In general, a photoresist film is barely attached to the transparent plate 10, however, it is strongly attached to the blocking layer 14. Therefore, the sacrificial photoresist film 16 is stably formed on the blocking layer 14.

Referring to FIGS. 3A and 3B, the sacrificial photoresist film 16 is selectively exposed to light and developed, thereby forming a sacrificial photoresist pattern 16a for defining concave and convex portions 12a and 12b of the template 20 shown in FIGS. 1A and 1B.

The blocking layer 14 and the transparent plate 10 are then sequentially removed, thereby forming the concave and convex portions 12a and 12b on the transparent plate 10. For example, the blocking layer 14 is partially dry-etched away using the sacrificial photoresist pattern 16a as an etching mask, thereby forming a blocking pattern 14a on the transparent plate 10. The transparent plate 10 is continuously dry-etched away using the sacrificial photoresist pattern 16a as an etching mask, thereby forming the concave and convex portions 12a and 12b in a body with the transparent plate 10. The sacrificial photoresist pattern 16a on the blocking pattern 14a is completely removed, thus the blocking pattern 14a is formed on the transparent plate 10 including the concave and convex portions 12a and 12b. In a subsequent imprinting process, the concave portions 12a of the template 20 imprint a line of the photoresist pattern on the semiconductor substrate, and the convex portions 12b of the template 20 imprint a space of the photoresist pattern on the semiconductor substrate. Accordingly, the method of forming the template 20 does not remove the blocking pattern 14a from the transparent plate 10, thus simplifying the process for forming the template 20.

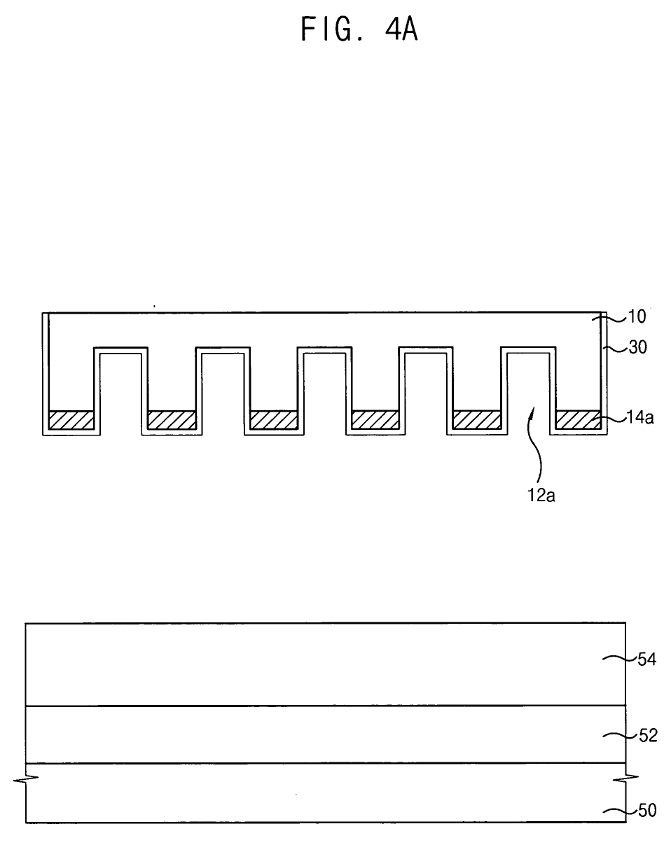

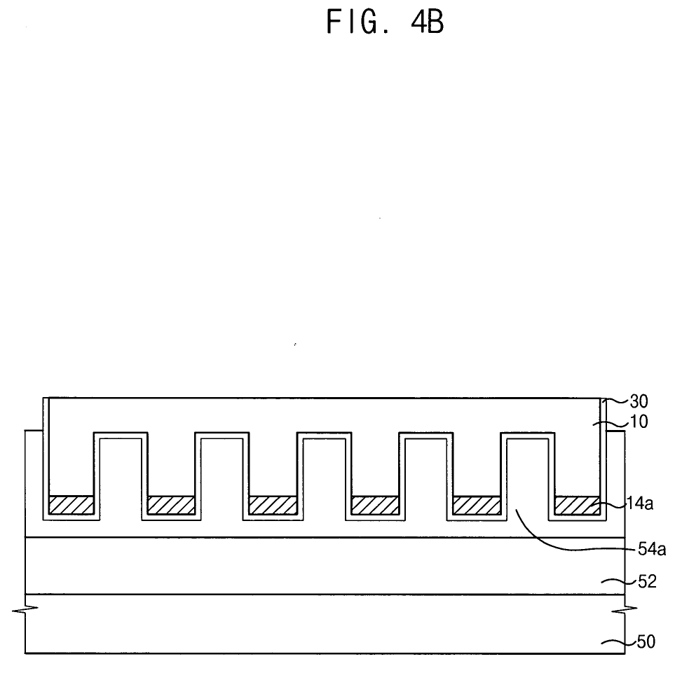

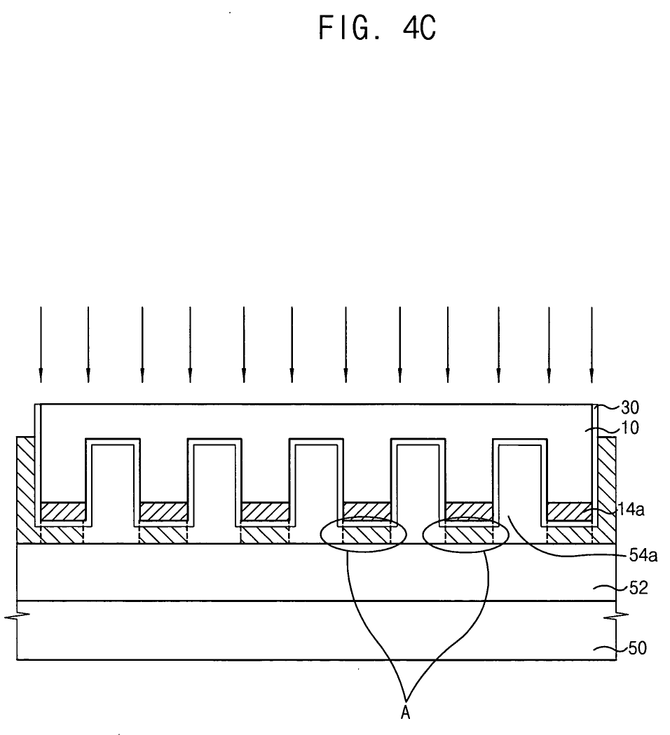

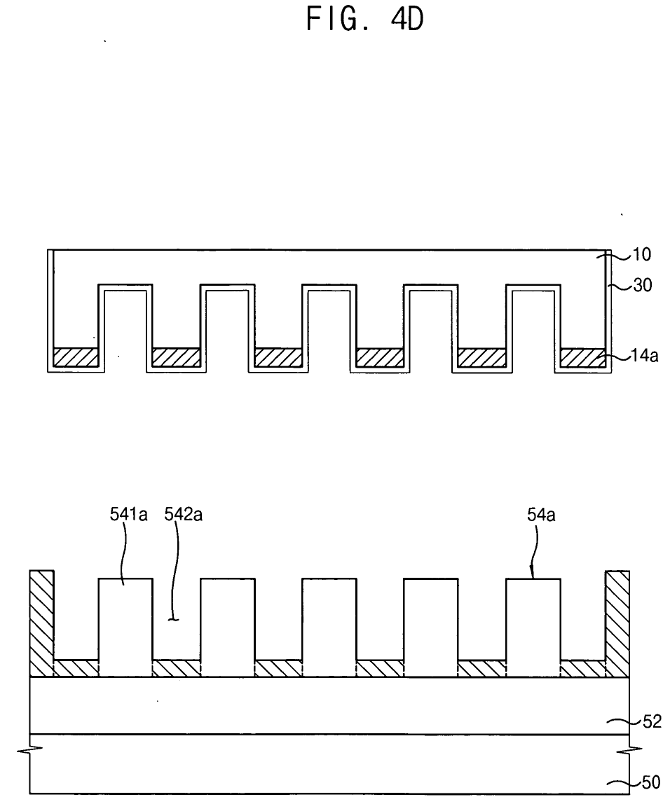

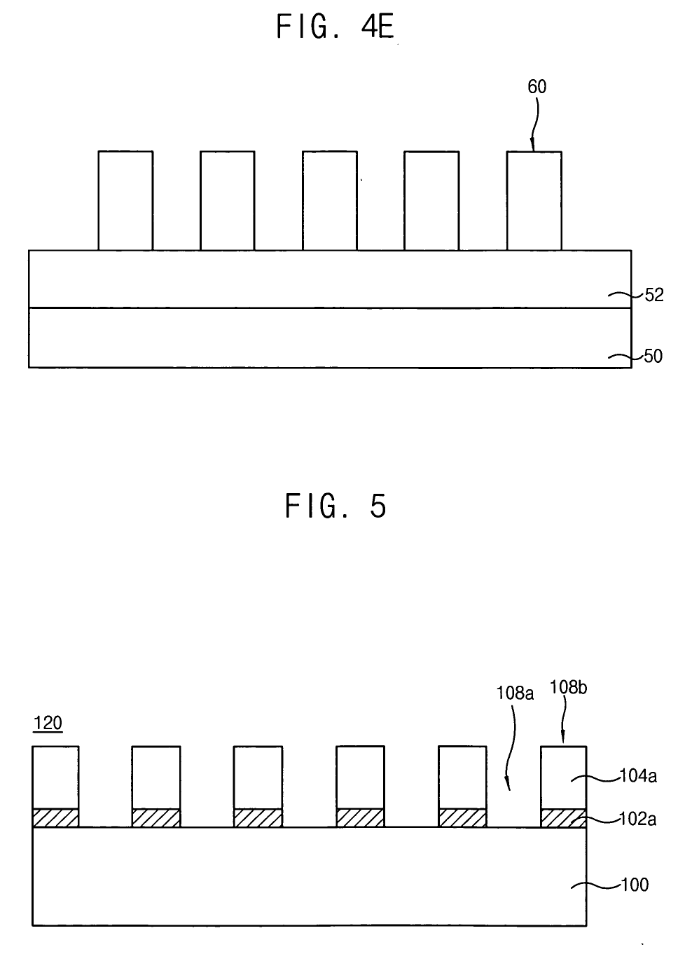

FIGS. 4A to 4E are cross sectional views illustrating processing steps of a method of forming a photoresist pattern on a semiconductor substrate using the template 20 shown in FIGS. 1A and 1B.

Referring to FIG. 4A, an objective layer 52 that is to be patterned using the template 20 is formed on a substrate 50 such as a semiconductor wafer. Although the first exemplary embodiment discusses forming a pattern on an objective layer on a substrate, the substrate itself or any other structure known to one of the ordinary skill in the art could also be patterned using the method as follows.

A photoresist film 54, for example a negative type film, is formed on the objective layer 52. In general, when light, for example ultra violet light (UV light), is provided onto the negative photoresist film 54 in an exposing process, a portion of the negative photoresist film 54 to which the light is irradiated during the exposing process is chemically reacted with a photo acid generator. Accordingly, the portion of the photoresist film 54 to which the light is irradiated is transformed into a polymer having a non-soluble property in a developer due to a cross-linked bond between the photoresist film 54 and the photo acid generator. For example, the portion of the negative photoresist film 54 to which the light is irradiated is not dissolved into the developer, and a portion of the negative photoresist film 54 to which no light is irradiated is dissolved into the developer, so that the portion to which no light is irradiated is formed into a pattern by the developing process. As an example, the negative photoresist film 54 comprises a saturated or an unsaturated resin formed by using an acrylate-based monomer such as t-butyl methacrylate and an acrylate including silicon, a photo acid generator, a cross-linking agent and a solvent. An imprinting material comprising a perflouro alkylene polymer is deposited on the template 20 shown in FIGS. 1A and 1B in a gaseous state, thereby forming an imprint material layer 30. The imprint material layer 30 facilitates the separation of the template 20 from the photoresist film 54 after the template is allowed to press on the photoresist film 54 in a subsequent process.

In detail, the perflouro alkylene monomer gas is mixed with an acid generator, and then the perflouro alkylene monomer gas is transformed into a perflouro alkylene polymer by a polymerization. The perfluoro alkylene monomer is formed into a perflouro alkylene polymer by polymerization on a surface of the template 20, thereby forming the imprint material layer 30. Examples of the perflouro alkylene monomer include tetrafluoro ethylene, perflouro propylene, perflouro butylenes, etc. A conventional photo acid generator may be utilized as the acid generator.

Then, the template 20 is aligned on the photoresist film 54 such that the concave portion 12a thereof is aligned corresponding to a portion of the objective layer 52 that is to be formed into a line portion of the pattern.

Referring to FIG. 4B, the template 20 is allowed to lightly press onto the photoresist film 54, so that a transferred profile reverse the profile of the template 20 is formed on the photoresist film 54. For example, the photoresist film 54 is recessed at a portion corresponding to the convex portion 12b of the template 20, and is protruded at a portion corresponding to the concave portion 12a of the template 20. The template 20 is allowed to very lightly press onto the photoresist film 54, so that the objective layer 52 under the photoresist film 54 is spaced apart by a predetermined distance therefrom.

Therefore, the above imprinting process forms the recessed portion corresponding to the convex portion 12b and the protruded portion corresponding to the concave portion 12a on the photoresist film 54.

Referring to FIG. 4C, light is irradiated onto the template 20 that presses onto the photoresist film 54, so that the photoresist film 54 is selectively exposed to the light selectively passing through the template 20, which is referred to as a UV (ultraviolet) light curing process. As an example, the light has a wavelength less than or equal to about 633 nm. That is, the photoresist film is formed into a minute pattern having a line width of no more than 100 nm even though a wavelength of the light in an exposure system is not sufficiently short for the minute pattern.

The light then passes through the concave portion 12a of the template 20, and is blocked by the blocking pattern 14 formed on the convex portion 12b of the template 20. Therefore, the light is not irradiated to a portion A of the photoresist film 54 corresponding to the convex portion 12b, and the portion A of the photoresist film 54 is dissolved into the developer.

For example, when the light is selectively irradiated to the photoresist film 54 through the template 20 that presses the photoresist film 54, the photoresist film 54 corresponding to the concave portion 12a to which the light is irradiated is hardened and the photoresist film 54 corresponding to the convex portion 12b to which the light is not irradiated is dissolved into the developer, thereby forming a preliminary photoresist pattern 54a.

Referring to FIG. 4D, the template 20 is separated from the preliminary photoresist pattern 54a. The preliminary photoresist pattern 54a includes a plurality of line portions 541a formed corresponding to the concave portion 12a and a plurality of spaces 542a between the line portions 541a formed corresponding to the convex portion 12b. Because the imprint material layer 30 is formed on a surface of the template 20 along the profile of the concave and convex portions 12a and 12b it facilitates the separation of the template 20 from the preliminary photoresist film 54a.

Referring to FIG. 4E, the preliminary photoresist pattern 54a is developed using a predetermined developer, thereby forming a photoresist pattern 60. For example, the photoresist material remaining in the spaces 542a is completely dissolved into the developer and removed from the objective layer 52, so that the line portions 541a only remain on the objective layer 52, thereby forming the photoresist pattern 60. The photoresist pattern 60 functions as a mask pattern for etching the objective layer 52.

Accordingly, an additional etching process for forming the photoresist pattern 60 successively to the above exposing process may be omitted, thus the fabricating process for a semiconductor device is further simplified. Furthermore, the photoresist pattern 60 is completed only using the developing process, thus the aspect ratio of the mask pattern is not reduced.

FIG. 5 is a cross sectional view illustrating a template 120 for forming a photoresist pattern according to a second exemplary embodiment of the present invention.

Referring to FIG. 5, the template 120 includes a transparent plate 100 comprising a transparent material such as quartz.

A top surface of the transparent plate 100 is planarized by a process such as a chemical mechanical polishing (CMP) process, and a blocking pattern 102a for selectively blocking the light passing through the transparent plate 100 is positioned on the top surface of the transparent plate 100 such that concave and convex portions 108a and 108b are defined thereon.

Then, a transparent layer is positioned only on the blocking pattern 102a corresponding to the convex portions 108b, thereby forming a transparent pattern 104a on the blocking pattern 102a. Accordingly, the transparent plate 100 is partially exposed through the concave portions 108a, and the transparent plate 100 is also partially covered by the convex portions 108b. For example, the blocking pattern 102a corresponding to the convex portions 108b only remains.

Therefore, when light is provided onto the template 120, the light partially passes through the transparent plate 100 via the concave portions 108a and is partially prevented from passing through the blocking pattern 102a corresponding to the convex portions 108b.

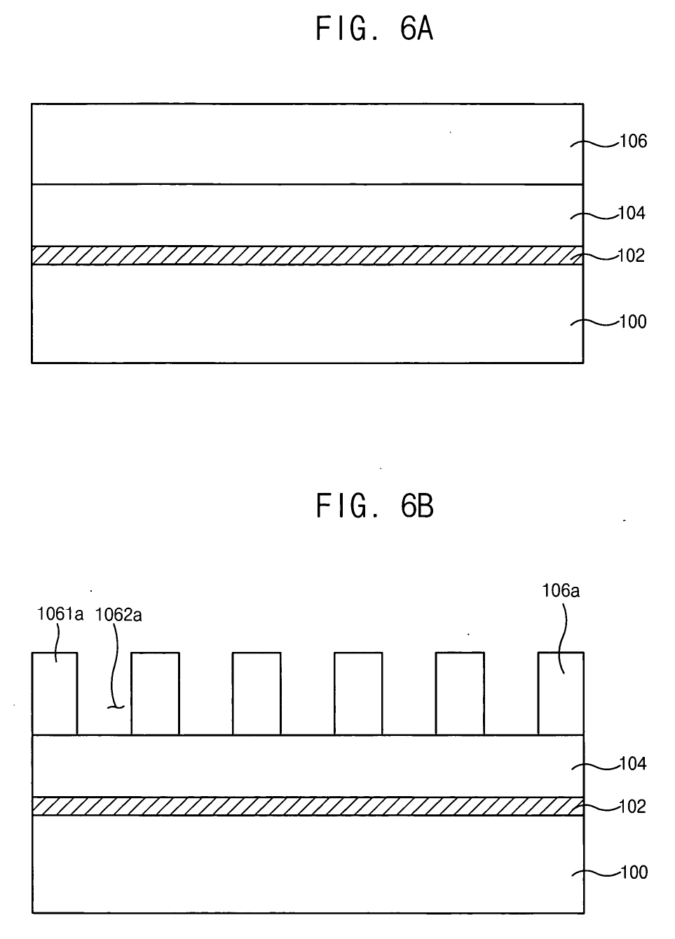

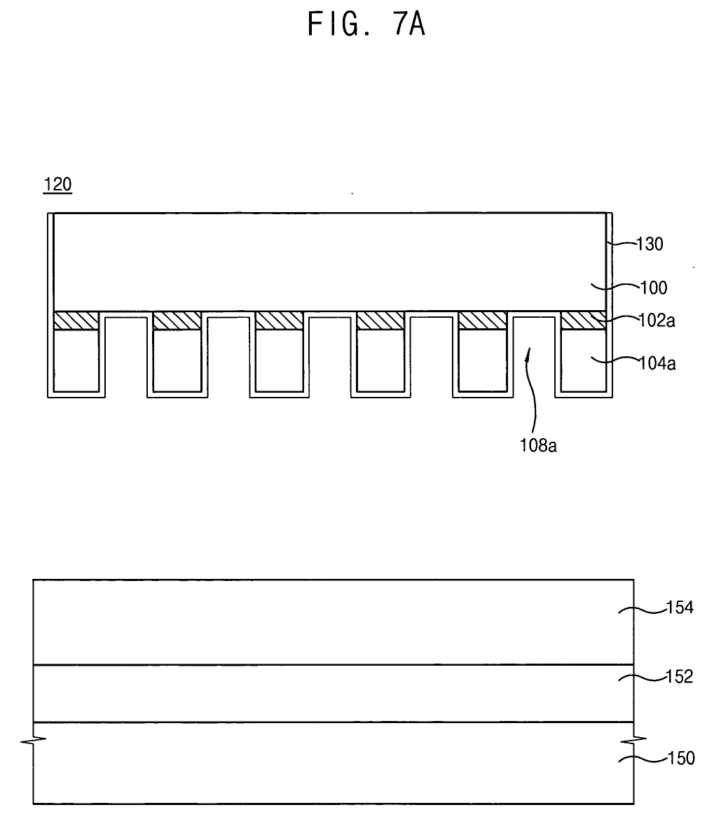

FIGS. 6A and 6B are cross sectional views illustrating processing steps of a method of forming the template 120 shown in FIG. 5.

Referring to FIG. 6A, a transparent plate 100 comprising a transparent material, for example quartz, is provided, and light passes through the transparent plate 100. A blocking layer 102 is formed on the transparent plate 100 for selectively blocking the light from passing through. For example, the blocking layer 102 may comprise Cr. A transparent layer 104 comprising silicon oxide is formed on the blocking layer 102, and light may penetrate the transparent layer 104. Then, a sacrificial photoresist film 106 is formed on the transparent layer 104.

Referring to FIG. 6B, the sacrificial photoresist film 106 is selectively exposed to light and developed, thereby forming a sacrificial photoresist pattern 106a for defining the concave and convex portions 108a and 108b on the transparent plate 100. The photoresist pattern 106a has a plurality of line portions 1061a corresponding to the convex portions 108b and a plurality of spaces 1062a between the line portions 1061a corresponding to the concave portions 108a.

Then, the transparent layer 104 and the blocking layer 102 are sequentially removed using a dry-etching process, and the sacrificial photoresist pattern 106a is completely removed, thereby forming the blocking pattern 102a and the transparent pattern 104a on the transparent plate 100 as shown in FIG. 5.

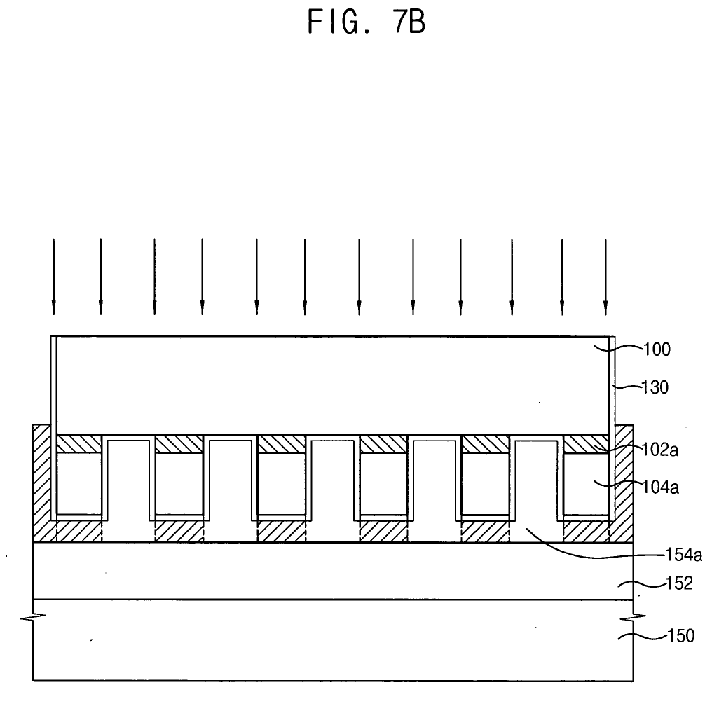

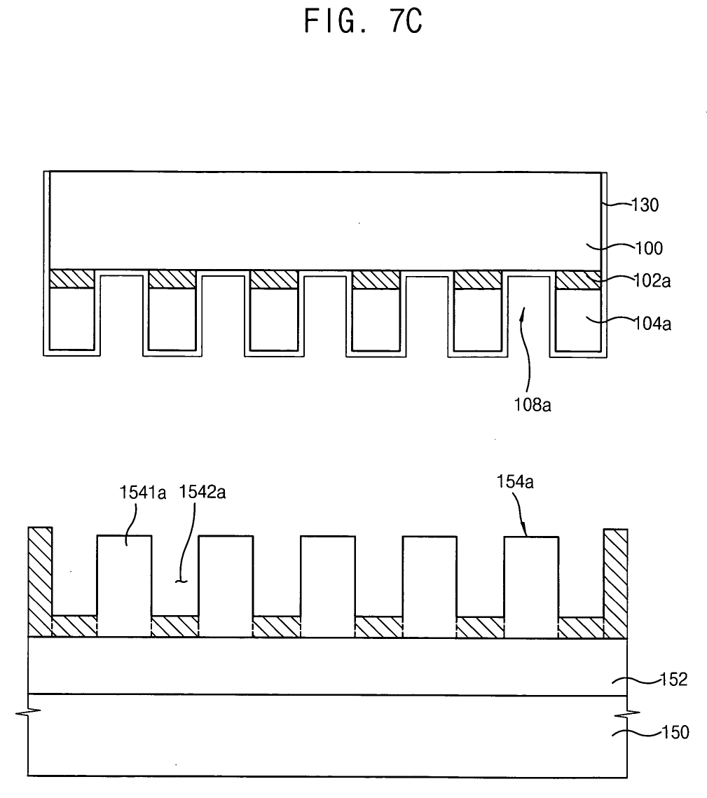

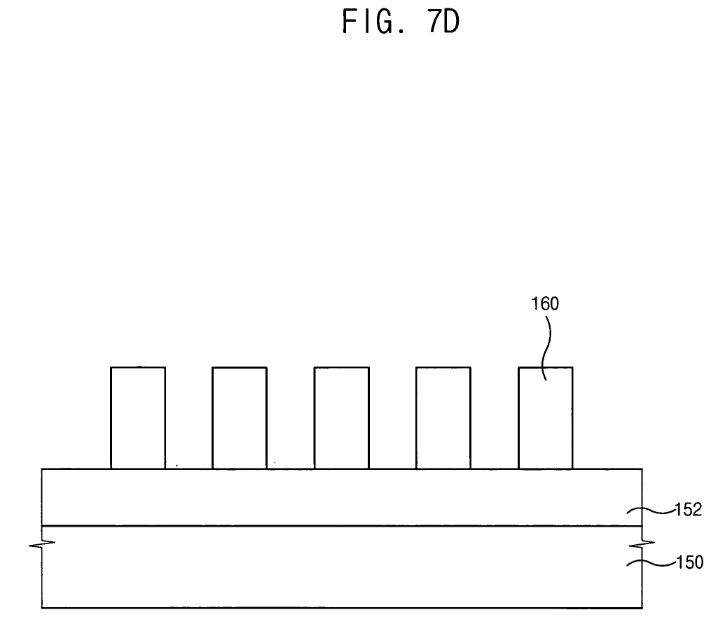

FIGS. 7A to 7D are cross sectional views illustrating processing steps of a method of forming a photoresist pattern on a semiconductor substrate using the template 120 shown in FIG. 5. The method of forming the photoresist pattern according to the second exemplary embodiment is very similar to the method of forming the photoresist pattern according to the first exemplary embodiment of the present invention except for the shape of the template.

Referring to FIG. 7A, an objective layer 152 that is to be patterned using the template 120 is formed on a substrate 150 such as a semiconductor wafer. Although the second exemplary embodiment discusses forming a pattern on an objective layer formed on a substrate, the substrate itself or any other structure known to one of the ordinary skill in the art could also be patterned using the same method as follows.

A negative photoresist film 154 is formed on the objective layer 152 in a similar way as described in the first exemplary embodiment of the present invention. Meanwhile, an imprint material layer 130 comprising a perflouro alkylene polymer is formed on the template 120 shown in a similar way as described in the first exemplary embodiment of the present invention. Then, the template 120 is aligned on the negative photoresist film 154 such that the concave portion 108a thereof is aligned corresponding to a portion of the objective layer 152 that is to be formed into a line portion of the pattern.

Referring to FIG. 7B, the template 120 is allowed to lightly press onto the photoresist film 154, so that a transferred profile reverse the profile of the template 120 is formed on the negative photoresist film 154. For example, the negative photoresist film 154 is recessed at a portion corresponding to the convex portion 108b, and is protruded at a portion corresponding to the concave portion 108a.

Therefore, the above imprinting process forms the recessed portion corresponding to the convex portion 108b and the protruded portion corresponding to the concave portion 108a on the photoresist film 154.

Light is irradiated onto the template 120 that presses the negative photoresist film 154, so that the photoresist film 154 is selectively exposed to the light selectively passing through the template 120. The light passes through the concave portion 108a, and is blocked by the blocking pattern 102a formed on the convex portion 108b. Therefore, the light is not irradiated onto a portion of the negative photoresist film 154 corresponding to the convex portion 108b, and the portion of the photoresist film 154 is dissolved into the developer.

For example, when the light is selectively irradiated to the negative photoresist film 154 through the template 120 that presses on the negative photoresist film 154, the negative photoresist film 154 corresponding to the concave portion 108a to which the light is irradiated is hardened and the negative photoresist film 154 corresponding to the convex portion 108b to which the light is not irradiated is dissolved into the developer, thereby forming a preliminary photoresist pattern 154a.

Referring to FIG. 7C, the template 120 is separated from the preliminary photoresist pattern 154a. The preliminary photoresist pattern 154a includes a plurality of line portions 1541a formed corresponding to the concave portion 108a and a plurality of spaces 1542a between the line portions 1541a formed corresponding to the convex portion 108b. Because the polymer layer including a perfluoro alkylene polymer is deposited on a surface of the template 120 along the profile of the concave and convex portions 108a and 108b thereof, it facilitates the separation of the template 120 from the preliminary photoresist pattern 154a.

Referring to FIG. 7D, the preliminary photoresist pattern 154a is developed using a predetermined developer, thereby forming a photoresist pattern 160. For example, the photoresist material remaining in the spaces 1542a is completely dissolved into the developer and removed from the objective layer 152, so that only the line portions 1541a remain on the objective layer 152, thereby forming the photoresist pattern 160. The photoresist pattern 160 functions as a mask pattern for etching the objective layer 152.

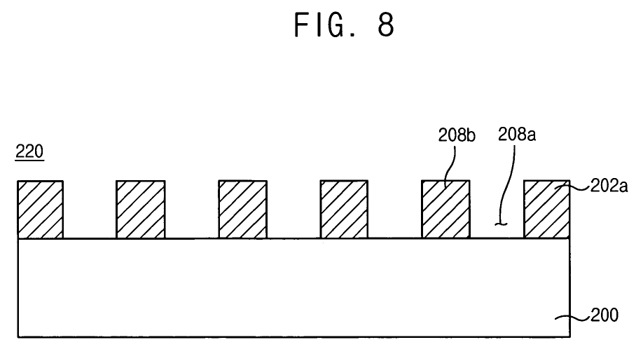

FIG. 8 is a cross sectional view illustrating a template 220 for forming a photoresist pattern according to a third exemplary embodiment of the present invention. Referring to FIG. 8, the template 220 includes a transparent plate 200 comprising transparent material such as quartz.

A top surface of the transparent plate 200 is planarized by a process such as a chemical mechanical polishing (CMP) process, and a blocking pattern 202a for selectively blocking the light passing through the transparent plate 200 is positioned on the top surface of the transparent plate 200 such that concave and convex portions 208a and 208b are defined thereon.

Then, a blocking pattern 202a is formed on the transparent plate 200, so that a portion of the transparent plate 200 is partially covered with line portions of the blocking pattern 202a corresponding to the convex portions 208b and is also partially exposed through spaces between the line portions corresponding to the concave portions 208a. The blocking pattern 202a may comprise a metal such as Cr.

Therefore, when light is provided onto the template 220, the light partially passes through the transparent plate 200 via the concave portions 208a and is partially prevented from passing through by the blocking pattern 202a corresponding to the convex portions 208b.

A blocking layer is formed on the transparent plate 200, and the blocking layer is partially removed by a conventional etching process, thereby forming the template 220. The photoresist pattern may be formed by the same method as described in the first and second exemplary embodiments of the present invention using the template of the third exemplary embodiment.

According to the present invention, the photoresist film is selectively exposed to light in an exposing system simultaneously with an imprinting process using a lithographic template, thus a photoresist pattern is formed not by an etching process but by a developing process. Accordingly, a fabrication process of a semiconductor device may be simplified because the etching process is not required. In addition, the aspect ratio of the pattern may be improved because the etching process is omitted.

Although the exemplary embodiments of the present invention have been described, it is understood that the present invention should not be limited to these exemplary embodiments but various changes and modifications can be made by one skilled in the art within the spirit and scope of the present invention as hereinafter claimed.

1. A template for forming a photoresist pattern, comprising:
a transparent plate;
a blocking pattern formed on the transparent plate for selectively blocking light passing through the transparent plate; and
a plurality of concave and convex portions formed in accordance with the blocking pattern for imprinting the photoresist pattern.

2. The template of claim 1, wherein the transparent plate comprises quartz.

3. The template of claim 1, wherein the blocking pattern comprises chrome (Cr).

4. The template of claim 1, wherein lines of the photoresist pattern are positioned on a semiconductor substrate along the convex portions, and spaces between the lines of the photoresist pattern are positioned along the concave portions.

5. The template of claim 4, wherein when the concave and convex portions are formed on the transparent plate the blocking pattern is positioned only on the concave portions.

6. The template of claim 4, wherein a top surface of the transparent plate is planarized, and the blocking pattern is positioned on the top surface of the planarized surface where the concave and convex portions are defined.

7. The template of claim 6, further comprising:
a transparent layer on the blocking pattern corresponding to the convex portions.

8. The template of claim 1, wherein a top surface of the transparent plate is in contact with a semiconductor substrate.

9. A method of forming a template by which a photoresist pattern is formed on a substrate, comprising:
forming a blocking layer on a transparent plate for selectively blocking light; and
partially removing the blocking layer and the transparent plate, so that a blocking pattern and a plurality of concave and convex portions are formed for imprinting the photoresist pattern.

10. The method of claim 9, wherein the step of removing the blocking layer and the transparent plate includes:
forming a removable photoresist pattern on the blocking layer for defining the concave and convex portions;
sequentially etching the blocking layer and the transparent plate using the removable photoresist pattern as an etching mask, so that the blocking pattern is formed on the transparent plate including the concave and convex portions; and
removing the removable photoresist pattern remaining on the blocking pattern.

11. A method of forming a photoresist pattern on a substrate, comprising:
forming a photoresist film on the substrate;
pressing a template on the photoresist film, wherein the template includes a transparent plate having a blocking pattern formed thereon for selectively blocking light passing through the transparent plate, and a plurality of concave and convex portions formed in accordance with the blocking pattern for imprinting the photoresist film;
partially exposing the photoresist film to light selectively passing through the template; and
developing the photoresist film that has been exposed to the light.

12. The method of claim 11, further comprising:
depositing a perflouro alkylene polymer along a surface of the template that is in contact with the photoresist film before pressing the template on the photoresist film.

13. The method of claim 11, wherein lines of the photoresist pattern are formed on the substrate along the convex portions, and spaces between the lines of the photoresist pattern are formed along the concave portions.

14. The method of claim 11, wherein the photoresist film is a negative type.

15. The method of claim 14, wherein the blocking pattern is formed on the concave portions.

16. The method of claim 14, wherein the blocking pattern is formed on the convex portions.

17. The method of claim 11, wherein the template presses the photoresist film when spaced apart from the substrate by a predetermined distance.

18. The method of claim 11, wherein the transparent plate comprises quartz.

19. The method of claim 11, wherein the blocking pattern comprises chrome (Cr).

20. The method of claim 11, wherein the light has a wavelength less than or equal to 633 nm.
